(19) United States
(12) Patent Application Publication
(10) Pub. No.: US 2015/0014024 A1
(43) Pub. Date: Jan. 15, 2015

(54) Jumper Fin

(71) Applicant: Kevin Yang, Lomita, CA (US)

(72) Inventor: Kevin Yang, Lomita, CA (US)

(21) Appl. No.: 13/940,930

(22) Filed: Jul. 12, 2013

(51) Int. Cl. H05K 1/02

(52) U.S. Cl. CPC H05K 1/0203
USPC 174/252

(57) ABSTRACT

A jumper fin has a substrate and an electronic component emitting heat. The electronic component is mounted to the substrate. A first fin is in the shape of a first jumper. The first jumper is mounted to the substrate at a first pair of jumper openings. The first jumper passes through the substrate at the first pair of jumper openings. The first jumper is mounted near the electronic component. The first jumper is formed as a metal wire. The first jumper is heat conductive. The first vent opening is formed on a surface of the substrate. The first vent opening is near the first jumper, and the first vent opening passes completely through the substrate. The second fin is in the shape of a second jumper, wherein the second jumper is mounted to the substrate near the electronic component.

### DISCUSSION OF RELATED ART

Electronic components are typically mounted to substrates such as printed circuit boards (PCB). These substrates can be prepared with a circuit having a trace and layout. The circuit conducts electricity to provide electrical power to electrical components on the substrate. Unfortunately, some electronic components can generate a substantial amount of heat. LED elements mounted to circuit boards can create a substantial amount of heat. A wide variety of different types of heatsinks and fins have been devised for handling heat dissipation of electronic components. All electronic components generate a certain amount of heat.

A modern example of the typical LED board is illustrated by U.S. Pat. D681263, published on Apr. 30, 2013. The inventors, Van Eekeren, Simard, and Pelch's LED display module consists of a substrate with multiple LEDs packed tightly next to each other to generate a lighted display board. Other types of LED circuit boards emphasize a unique arrangement of LEDs, such as Wollard U.S. D675347. The rectangular array layout of his LEDs is shaped similar to arrows, and each arrow is placed vertically as well as horizontally parallel to one another on a PCB. In this type of pattern, the display module appears to be directing a viewer towards a certain way once this display is lighted.

The previously listed inventions focused on heat dissipation methods through the arrangement of LEDs; other inventors emphasized the importance the LED's enclosure. For example Ding US2013/0039074 proposed a method of cooling. In his design he refers to a rectangular enclosure, with the middle of this enclosure increasing in height towards the center (angular convex shape). The center is designed with multiple slit-like apertures to allow air to move inward, while the sides of the case are also marked with the same type of openings that enable outward airflow. The convex center is what allows for the occurrence of convection cooling.

### SUMMARY OF THE INVENTION

A jumper fin has a substrate and an electronic component emitting heat. The electronic component is mounted to the substrate. A first fin is in the shape of a first jumper. The first jumper is mounted to the substrate at a first pair of jumper openings. The first jumper passes through the substrate at the first pair of jumper openings. The first jumper is mounted near the electronic component. The first jumper is formed as a metal wire. The first jumper is heat conductive. The first vent opening is formed on a surface of the substrate. The first vent opening is near the first jumper, and the first vent opening passes completely through the substrate. The second fin is in the shape of a second jumper, wherein the second jumper is mounted to the substrate near the electronic component.

The second jumper is generally parallel to the first jumper. The substrate is an elongated strip shaped circuit board. The second jumper and the first jumper are electrically conductive. The second jumper has a second pair of jumper bends that fit through a second pair of jumper openings. The second jumper and the first jumper are non-insulated wire. The first vent opening is rounded and has a first vent opening sidewall. The first vent opening is aligned over the first jumper, and a second vent opening is aligned over the second jumper, wherein the second vent opening is formed on the substrate, wherein the second vent opening has a second vent opening sidewall.

The second jumper is generally parallel to the first jumper. Preferably, the second jumper has a second pair of jumper bends that fit through a second pair of jumper openings. Preferably, the second jumper and the first jumper are made of metal wire. The jumper fin passes through the jumper opening. The first vent opening is formed as a pair of drilled holes, and the second vent opening is formed as a pair of drilled holes.

### BRIEF DESCRIPTION OF THE DRAWINGS

FIG. 1 is a close-up bottom perspective view of the present invention.

FIG. 2 is a bottom perspective view of the present invention.

FIG. 3 is a bottom view of the present invention.

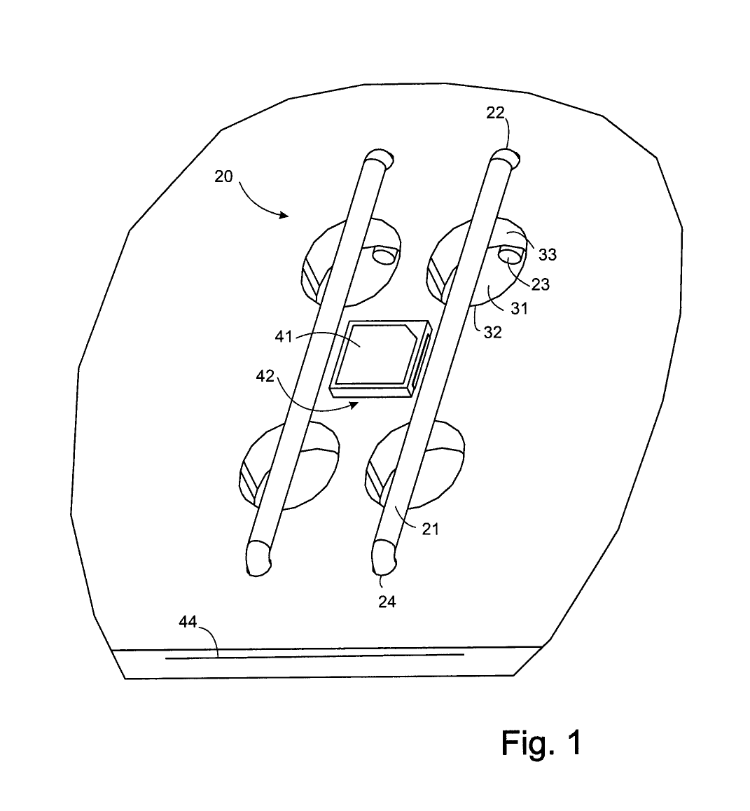

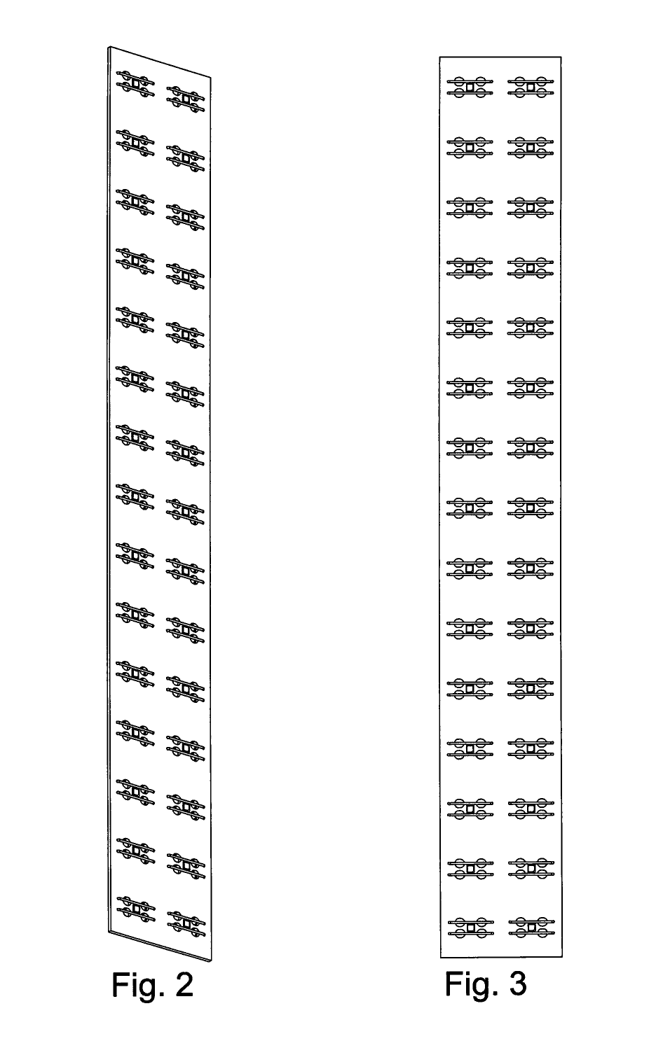

The following callouts as to the elements can be a useful guide in referencing the elements of the drawings.
20 Fin
21 Jumper Wire
22 Jumper Bend
23 Jumper Tip
24 Jumper Opening
31 Air Vent
32 Vent Edge
33 Vent Sidewall
41 Led Chip
42 Substrate Surface (PCB Surface)
43 Led Chip Mounting Area

### DETAILED DESCRIPTION OF THE PREFERRED EMBODIMENT

According to the first figure, a variety of components or mounted to a substrate which is shown in reverse orientation. Typically, a lamp is shown with elements pointing down and with a circuit portion pointing upward.

A fin 20 is formed of a jumper 21. The jumper 21 is a typical wire placed on the printed circuit board preferably by an automated machine. The jumper can be a copper clad wire such as copper clad aluminum. The jumper is preferably cut automatically as well. The jumper can be installed by a machine in a rapid movement. The jumper is electrically conductive and ease designed to be electrically conductive, but in this case is being used for its thermal conductivity properties instead of its electrically conductive properties. The jumper 21 preferably includes a straight portion and a pair of jumper bends 22 at a first and second end of the jumper 21. The first bend terminates at a first jumper tip 23. The second bend terminates at a second jumper tip 23. The jumper passes through the substrate at a jumper opening formed on the substrate surface 42.

Preferably, fin 20 formed as the jumper is installed in pairs on a left and right side of an electronic component. The electronic component can be an LED chip 41. The LED chip is preferably mounted on an LED chip mounting area 43 that is located on the substrate. The substrate can be a printed circuit board. The printed circuit board preferably also includes a circuit etched on an upper, lower or intermediate portion of the substrate.

Additionally, an air vent 31 is formed adjacent to or under the jumper. The air vent has a vent sidewall 33. The vent can be circular to allow airflow through the vent during natural or forced convection. The vent sidewall 33 is preferably perpendicular to the substrate surface 42. Airflow passes through the vent and around a vent edge 32. As the airflow passes through the vent 31, it provides connection cooling to the electronic component. The airflow also provides cooling to the jumper. Preferably, the air vent 31 overlies the jumper so that airflow passing through the vent will blow across the jumper.

The jumper preferably has a circular cross-section, but could have a square or rectangular cross-section for improved turbulence and heat transfer flowing across its cross-section. Additionally, the jumper could be doubled up so that there are two jumpers on the left and two jumpers to the right of the heat emitting electronic component.

Jumpers 21 pass through jumper openings 24. The jumper openings are formed on the substrate allowing the jumpers to pass entirely through the substrate. After the jumpers pass through the substrate, the jumper tips 23 are bent to form the jumper bend 22. The jumpers thus have a staple like configuration with a straight portion and a pair of bent portions extending from the straight portions. Some jumpers have electrical connectors attached to them. It is preferred that the jumper is a wire only embodiment, having an end that is cut. The ends can be soldered or not soldered to the substrate. The substrate can be a printed circuit board that is drilled, or can be a metal board. A circuit is preferably disposed on the substrate so that the circuit carries electricity and electrical power to the electronic component mounted on the substrate.

The first figure shows the preferred embodiment of the present invention. The jumpers 21 are not soldered to the printed circuit board. Jumpers could be soldered to the printed circuit board. Commercially available jumpers are either insulated or non-insulated. The best mode is to have non-insulated jumpers.

The components should be near to each other, that is close enough so that the jumper can receive heat transfer from the electronic component and close enough so that the vent edge can provide airflow across a surface of the jumper. Heat flow begins at the electronic component and then conducts along the jumper. The jumper then loses heat by convection when airflow receives heat from the jumper. In this situation, the word ‘near’ means less than 2 mm, and including preferably overlaying, which would be zero millimeters.

The electronic component is preferably an LED chip. A plurality of LED chips could be arranged in an array, each of less than quarter watt to provide distributed heat generation as well as distributed light. When the array of LED chips is being used, it is preferred to have a jumper to the left and right of each chip. Each jumper should preferably include one or a pair of vent openings for cooling the jumper. The left jumper and the right jumper are named taken from a view of the user looking at the configuration from a view parallel to the jumper orientation.

Additionally, jumpers can be overlapped so that a left and right jumper are overlapped by a front and rear jumper. The front and rear jumper could also share the same vent holes or be near to them, namely at least within 2 mm. The jumpers can be installed to the component side of the substrate or the reverse side of the substrate. Components are typically mounted to the component side of the substrate, but substrates can receive jumpers on the reverse side as well. Jumpers on the reverse side can be parallel to or perpendicular to the left and right jumper. A user looking at a pair of jumpers may not notice that one is on the left and one is on the right, but the substrate can be turned so that the user has a jumper on the left and a jumper on the right. Preferably, the jumpers are parallel to each other and also square to the LED chip, assuming that the LED chip is square or rectangular in nature so as to have a straight edge capable of being aligned to the jumpers. The vents are also preferably aligned to the jumpers so that they are square in orientation to the jumpers.

An array or matrix of LED chips and jumpers can be installed on a strip of printed circuit board that has trace or does not have trace. The strip of printed circuit board is preferably sized so that it can receive components by automated PCB assembly techniques. The vent holes are preferably drilled by CNC machines on continuous process.

The diameter of the vent hole is preferably about three times the diameter of the jumper. The vent is preferably aligned and centered directly over the wire jumper. The vent hole can also be made elongated having a first and second radius of curvature at a first and second end of the vent hole.

1. A jumper fin comprising:
a. a substrate;
b. an electronic component emitting heat, wherein the electronic component is mounted to the substrate;
c. a first fin in the shape of a first jumper, wherein the first jumper is mounted to the substrate at a first pair of jumper openings, wherein the first jumper passes through the substrate at the first pair of jumper openings, wherein the first jumper is mounted near the electronic component, wherein the first jumper is formed as a metal wire, wherein the first jumper is heat conductive;
d. a first vent opening formed on a surface of the substrate, wherein the first vent opening is near the first jumper, wherein the first vent opening passes completely through the substrate.

2. The jumper fin of claim 1, further comprising:
a. a second fin in the shape of a second jumper, wherein the second jumper is mounted to the substrate near the electronic component.

3. The jumper fin of claim 2, wherein the second jumper is generally parallel to the first jumper.

4. The jumper fin of claim 2, wherein the substrate is an elongated strip shaped circuit board.

5. The jumper fin of claim 2, wherein the second jumper and the first jumper are electrically conductive.

6. The jumper fin of claim 2, wherein the second jumper has a second pair of jumper bends that fit through a second pair of jumper openings.

7. The jumper fin of claim 2, wherein the second jumper and the first jumper are non-insulated wire.

8. The jumper fin of claim 2, wherein the first vent opening is rounded and has a first vent opening sidewall.

9. The jumper fin of claim 2, wherein the first vent opening is aligned over the first jumper, wherein a second vent opening is aligned over the second jumper, wherein the second vent opening is formed on the substrate, wherein the second vent opening has a second vent opening sidewall.

10. The jumper fin of claim 9, wherein the second jumper is generally parallel to the first jumper, wherein the second jumper has a second pair of jumper bends that fit through a second pair of jumper openings, wherein the second jumper and the first jumper are made of metal wire.

11. The jumper fin of claim 10, wherein the first vent opening is formed as a pair of drilled holes, wherein the second vent opening is formed as a pair of drilled holes.

12. The jumper fin of claim 10, wherein the first vent opening is rounded and has a first vent opening sidewall.

13. The jumper fin of claim 10, wherein the substrate is an elongated strip shaped circuit board.

14. The jumper fin of claim 10, wherein the second jumper and the first jumper are electrically conductive.
